(19) United States
(12) Patent Application Publication
(10) Pub. No.: US 2024/0186464 A1
(43) Pub. Date: Jun. 6, 2024

(54) CONVERTER AND METHOD FOR PRODUCING THE SAME

(71) Applicant: ams-OSRAM International GmbH, Regensburg (DE)

(72) Inventors: Zhengbo YU, Shrewsbury, MA (US); Maxim TCHOUL, Winchester, MA (US); Jeffery SERRE, Peabody, MA (US)

(21) Appl. No.: 18/074,216

(22) Filed: Dec. 2, 2022

(51) Int. Cl. H01L 33/50

(52) U.S. Cl. CPC H01L 33/502; H01L 2933/0041

(57) ABSTRACT

The present invention concerns a method of ultra-low temperature sintering for making a composite material which is useful for composite converters. The invention also concerns a composite material comprising a phosphor and a polymer, wherein the polymer is selected from polymethylsilesquioxane (PMSQ) or polysilesquioxane (PSQ), and wherein the composite material has a surface roughness below 1.000 μm.

The present invention concerns a method of ultra-low temperature sintering for making a composite material which is useful for composite converters. A further object of the invention is a composite material, a composite converter and composite materials and composite converters prepared by the method as described herein.

### BACKGROUND

In most lighting applications based on LEDs for white light, the blue light emitted by an GaN or InGaN-LED is absorbed by a converter (phosphor or luminescent material) that can re-emit the absorbed energy in the form of photons with a longer wavelength and lower energy. Such assemblies can also be called “down-converters”. When down-converters are chosen properly, the resulting LED can emit light of different colors depending on the specific combination of transmitted blue light from the LED plus other colors emitted from one or more phosphors present as luminescent material. For most down-conversion assemblies, the converters are in the form of either monolithic ceramic or composite, the latter normally includes ceramic phosphor in glass, ceramic phosphor in polymer etc. The converters are usually attached to the blue LED chip surface through a thin layer of glue.

This invention is to address the problem of high level of surface roughness or some surface spikes (with height taller than 1 μm) of the converters which can cause the epitaxy (Epi) of blue LED chip damage during assembly process. For example, FIG. 1 schematically shows the surface epitaxy (Epi) of a blue LED chip damaged by the protrusions or spikes of the converter having excessively high surface roughness. Such effect is observed in both polymer based composite converters produced by wet gelation process and in ceramic converters.

A typical case in the package assembly causing the Epi damage is shown in FIG. 2, where the converter is in the form of a piece of monolithic ceramic platelet. Depending on the process, normally ceramic converters have a relatively low surface roughness (Sa<1.0 μm), but there still exist a certain population of ceramic converters from a lot with certain nodules or spikes on the surface and it is the potential root cause of damage to the Epi of a blue LED chip, resulting in disfunction or complete failure of the assembled package.

Phosphor-in-polymer composite converters made by wet process have gained a lot of attention in recent years because of their high brightness, flexible color tuning and low cost. For example, US 2021/0189231 A1, US 2021/0253945 A1, U.S. Pat. No. 10,923,634 B1 and U.S. Pat. No. 10,727,378 B2 disclose the wet process.

However similar Epi damage cases were also observed in the polymer based composite converters produced by wet process, where large phosphor grains of different particle sizes are distributed in the polymer matrix, which result in a very high level of surface roughness and leads to a damage to the epitaxy (Epi) layer. The very high roughness of polymer based composite converters produced by wet gelation process presents a challenge since it is in-situ formed and is associated directly with its preparation process. During this process phosphors are mixed with liquid polymer precursor solution and certain gelation additives to form a homogenized slurry. The slurry is then cast into a thin film of desired thickness by tape cast or other cast processes. The thin film is then cured under certain temperature or by light of certain wavelength depending on the type of the polymers used.

For example, a reactive liquid methyl silicone resin, which serves as a binder, cures at ambient or elevated temperature in the presence of catalysts e.g., tetra-n-butyl-titanate etc. and moisture (approx. 12 hours depending on the type of precursor); followed by baking or forced drying, e. g. in a convection oven, the latter is also possible in presence of air humidity. The gelation (cross-linking) proceeds via a hydrolysis/condensation and normally result in a very high-volume shrinkage (as high as 30%). This large volume shrinkage causes a very high level of surface roughness as well as micro- or macro-cracks within the thin film, which affect the optical performance and service life. The fillers are often introduced in the formulation to reduce the relative shrinkage, but this affects optical properties of the converters. The reaction occurring in the liquid process described above (named as wet process) can be schematically illustrated in FIG. 3 using methoxy functionalized methyl polysiloxane based polymer as an example.

This invention is to solve the problems of the severe surface roughness, high surface spikes/peaks, and microcracks encountered in the wet process of making polymer-based converters in which gelation occurs by introduction of chemical additives (or by light of certain wavelength).

### SUMMARY OF THE INVENTION

This and other objects are addressed by the subject matter of the independent claims. Features and further aspects of the proposed principles are outlined in the dependent claims.

According to a first aspect of the invention, a composite material is provided, the composite material comprising a phosphor and a polymer, wherein the polymer is selected from polymethylsilesquioxane (PMSQ) or polysilesquioxane (PSQ), and wherein the composite material comprises a surface roughness below 1.0 μm, preferably below 0.5 μm.

According to a further aspect of the invention, a composite converter and an optoelectronic device is provided, the composite converter and optoelectronic device comprising the composite material as described herein.

According to another aspect of the invention, a method of manufacturing a composite material is provided, the method comprising the steps:
a. Mixing phosphor powder and PMSQ or PSQ powder in a solid state;
b. Homogenizing the mixture;
c. pressing and extruding the mixture at a temperature from 50° C. to 500° C.

In some aspects, the temperature for pressing and extruding is from 70° C. to 400° C. and particularly between 100° C. and 250° C. In some further aspects, the temperature is a single value, for example taken from the range between 100° C. and 400° C., for example 130° c. 140° C., 150° C., 160° C. and 180° C.

In some further aspects, the composition will be heated up to or above said temperature. The heat-up time to said temperature may range from 2 min to 40 min and in particularly between 5 min to 25 min and more particularly between 10 min to 20 min. In some aspects, the heat up time is specified in ° C. per min, so for example between 10° C. per min to 20° C. per min.

The dwelling time at the above given temperature examples is between 15 min and 60 min and particularly between 20 min and 50 min.

The heated die set may be set under an uniaxial pressure of ˜75 psi to 300 psi or even higher depending on volume percent of each component. such pressure can be held for 2 minutes to 15 minutes.

After releasing the pressure, the pressed densified disc may be kept at the above temperature for 1 hour to 20 hours to make the gelatin/cross-link process of the polymers in the powder mixture completed. Other holding times may range from 30 minutes to 18 hours or also from 2.5 hours to 18 hours an more particularly between 5 hours to 12 hours. In some aspects, the holding temperature may be set independent from the temperature at which the unaxial pressure is applied. For example in some aspects, the holding temperature may range between 70° C. to 150° C. or from 100° C. to 130° C. and may be in instances lower than the temperature at which the unaxial pressure is applied.

### SHORT DESCRIPTION OF THE DRAWINGS

Further aspects and embodiments in accordance with the proposed principle will become apparent in relation to the various embodiments and examples described in detail in connection with the accompanying drawings in which:

FIG. 1 shows a schematic drawing illustrating the damage of the surface epi of a blue LED chip by the high roughness surface of a converter.

FIG. 2 shows an example of an image of a dented and damaged epi surface (upper image) and an example image of an extrusion on the surface of a ceramic converter (lower image).

FIG. 3 shows a wet process—gelation (cross-link) of liquid methoxy functionalized methyl polysiloxane based polymer induced by catalyst and moisture with large amount of water and methanol released)(<200° C. according to the state of the art.

FIG. 4 shows a dry process—gelation (cross-link) of solid polymethylsilsesquioxane (PMSQ) based resin induced by heat/pyrolysis with very small amount of water and methanol released) (<200° C. according to some aspects of the invention.

FIG. 5 shows schematic drawings as an example illustrating the advantage and process of some technical features of the invention.

FIG. 6 shows color chromaticity of white composite converter materials made in an embodiment of the invention with (a) illustrating the conversion line Cx vs Cy; and (b) illustrating the conversion efficacy (CE) vs color point (Cx).

FIG. 7 shows a typical white composite converter material disc made by pressing and extruding according to the invention following the process described in example 3.

FIG. 8 shows the color point and brightness of an amber composite converter materials as shown in examples 14 and 15 with (a) illustrating the color point (Cx, Cy); and (b) illustrating conversion efficacy (CE) vs color point (Cx).

FIG. 9 shows a typical amber composite converter material disc made by the pressing and extruding process according to some aspects of the invention (cf. Example 13).

FIG. 10 shows a typical amber composite converter material disc diced into square shape platelets of dimension ˜1150×1150 μm according to some aspects of the invention.

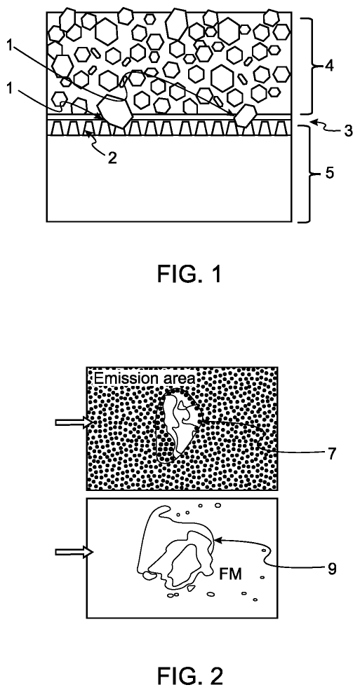

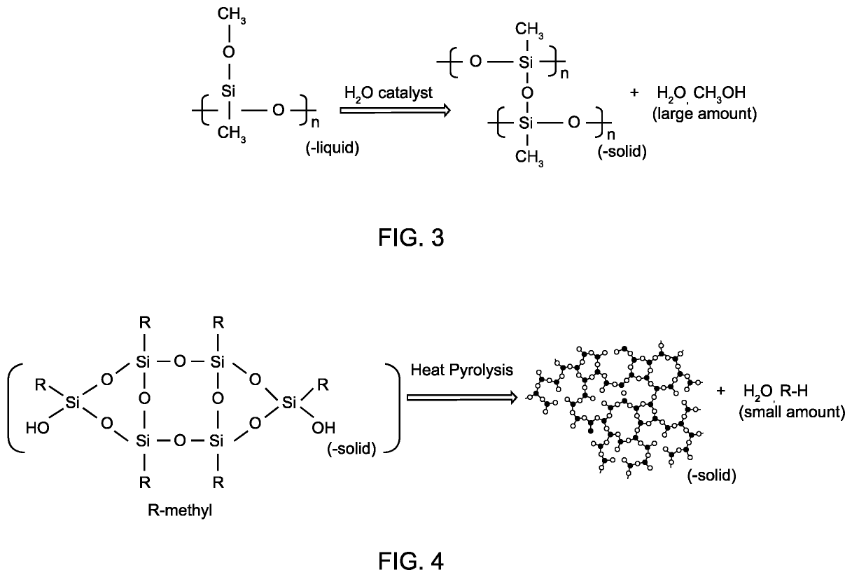

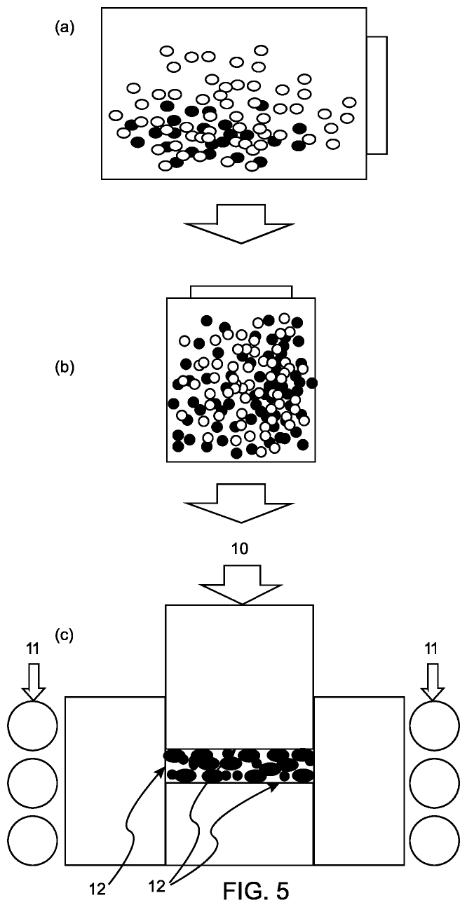

### DETAILED DESCRIPTION

In this invention, a dry process comprising of pyrolysis and sintering at ultra-low temperature assisted by external force (pressing and extruding etc.) was used to make polymer and/or glass based converters with very low surface roughness and no microcracks with dimension above micro-level. In brief, this invention uses dry powders of polymethylsilsesquioxane (PMSQ) containing small amount of silanols (hydroxyls), characterized by hydroxyls percent amount (—OH), ranging from 0.5% to 15.08, with preferred range from 1.0% to 10.0%, and with more preferred range from 1.08 to 8.08, and most preferred from 2.5% to 6%, where PMSQ is normally with a simplified basic structure [CH₃SiO_{1.5}]ₙ. It can be cured at elevated temperatures or transformed into a mixture of polymer/glass at elevated temperatures. This process is schematically illustrated in FIG. 4, the structures of the chemicals used in FIG. 4 are just for example, not necessary the exact chemical with the formula as they are a family of chemicals and can be represented by different ways.

Up to now the problem mentioned above has not been solved effectively yet, though several methods were proposed and tried, these include (1) introduction of solid polymer based fillers (micro- or nano-level size) into wet process to reduce the volume shrinkage to some extent, hence reduce surface roughness e.g. from several micrometers to approximately one micrometer. However, this method will reduce the brightness of up to 2% as observed as the effective volume of fillers (micro-beads etc.) reaches 15 vol. 8. If lower amount of fillers (e.g. micro-beads) are used, then the reduction of roughness is not effective. (2) Applying a thin layer of polymer to smooth the surface and hence reduce the roughness, this will also in turn affect the brightness and is not cost-effective.

By combination of the following technical features of the invention, the problem is solved as below:
Usage of dry solid starting chemicals of controlled range of molecular weight, for example, ranging from ˜3000 to ˜30000, with preferred range from 4000 to 18000, with more preferred range from 5000 to 12000 depending on the application and processing conditions chosen.
Application of heat/pyrolysis to induce the gelation (cross-link) with densification occurring simultaneously.
Employment of external force—pressing & extruding tool with flat and smooth surfaces to impart a low surface roughness (Sa) of the composite converter materials.

The invention therefore provides a composite material comprising a phosphor and a polymer, selected from polymethylsilesquioxane (PMSQ) or polysilesquioxane (PSQ), wherein the composite material has a surface roughness (Sa) below 1.000 μm. Preferably the surface roughness is smaller than 0.900 μm, more preferably smaller than 0.800 μm. The surface roughness is preferably between 0.200 μm to 1.000 μm, more preferably between 0.200 μm to 0.800 μm and most preferred between 0.200 μm to 0.500 μm.

Compositions according to the prior art, even ceramic monolithic systems as well as the composite systems prepared according to the wet process known in the prior art, show many spikes and nodules with height above 1.000 μm or even several micrometers which may protrude through the glue layer and damage the Epi layer. The composite material of the invention reduces spikes and nodules with height above 1.000 μm by more than 90%, preferably more than 95% and most preferably more than 99%. This is achieved by the specific manufacturing process, in which, among other aspects, a wet process as in the conventional art is avoided.

The phosphor is preferably selected from white phosphors comprising Gd and/or Ce doped YAG, green phosphors, comprising Ce doped LuAG, LuYAG, amber phosphors comprising Eu doped (Sr, Ba)₂Si₅Ne, or IR and/or NIR phosphors comprising La₃Ga₅GeO₁₄:Cr³⁺, ScBO₃:Cr³⁺, Gd₃Sc₂Ga₃O₁₂:Cr³⁺ and Mg₂SiO₄:Cr³⁺ and mixtures thereof. However, any other phosphors known in the art or combinations thereof can be applied here.

The phosphor comprises in some aspects a particle size from 10 nm to 50 μm. The D50 value (particle size distribution) is in that case about 30 μm. in some further aspects, the particle size ranges from 50 nm to 30 μm. The D50 value in that case is about 20 μm. In even some further aspects, some of them preferred the particle size of the phosphors is from 100 nm to 20 μm. The D50 value in that case is about 15 μm. Particle Size Distribution D50 is also known as the median diameter or the medium value of the particle size distribution; it is the value of the particle diameter at 503 in the cumulative distribution and considered to be an important parameter characterizing the particle size. D50 is usually used to represent the particle size of a group of particles. The particle size distribution can be determined with a commercially available particle size analyser.

The PMSQ or PSQ comprises a basic structure with the empirical formulae [RSiO_{1.5}]ₙ, wherein R is hydrogen or any alkyl, alkylene, aryl, arylene, or organo-functional derivatives of alkyl, alkylene, aryl, or arylene groups.

The PMSQ or PSQ comprises a particle size from 10 nm to 300 μm. The D50 value (particle size distribution) is in that case about 80 μm. Further preferred is that the particle size is from 100 nm to 50 μm. The D50 value in that case is about 30 μm. More preferred the particle size of the PMSQ or PSQ particles in the powder is from 100 nm to 30 μm. The D50 value in that case is about 15 μm. The particle size distribution can be determined with a commercially available particle size analyser. Consequently, the phosphor may comprise in some aspects the same size of the same D50 value as the PMSQ. In some other aspects, the D50 value of the PMSQ may slightly be larger than the D50 value of the phosphor.

The composite material has a softening point preferably between 50° C. to 500° C., more preferred 70° C. to 400° C., and more preferred 70° C. to 300° C. The composition of the composite may vary and is usually depending on the thickness of the composite material and the concentration of the phosphor within the composite.

The composite material can be used as a composite converter. Preferably the converter is a “down-converter”. The composite material can be applied to a main emission surface like an SiO₂ surface or an ITO-surface (Indium-tin oxide) of an optoelectronic device by means known in the art such as gluing or other coating means. The composite material according to the invention may also be directly coated to an active surface by lamination or other means known in the art. The optoelectronic device comprises semiconductor layer stack having an active region between an n-doped layer structure and a p-doped layer structure. The semiconductor layer stack also comprises a main emission surface, that is the surface through which light is emitted in operation of the layer stack. The composite converter is then attached to the main emission surface. In operation of such overall device, emitted light may be a pure converted light (full conversion), but also a light composition (partial conversion). For example, white light can be generated by a composite converter in accordance with the present invention and a corresponding blue LED.

The invention also provides a method of manufacturing a composite material, comprising the steps:
d. Mixing phosphor powder and PMSQ or PSQ powder in a dry state;
e. Homogenizing the mixture;
f. pressing and extruding the mixture at a temperature as from 50° C. to 500° C.

The mixing and/or homogenizing is performed by rolling, shaking, ball milling or the like. Every method known in the art is applicable here.

The temperature for pressing and extruding is from 50° C. to 500° C., more preferably from 70° C. to 400° C., and more preferred 70° C. to 300° C.

At such temperature the mixture becomes either molten or at least viscous, such that it can be pressed and/or extruded in the desired shape. The pressing takes place under a force of 10 psi to 1000 psi. The molten mixture will be pressed through an extrusion die with a diameter ranging from 5 mm to 200 mm.

The temperature at softening point will be hold for a certain period of time, e. g. from 2 minutes to 240 minutes, between 45 and 75 minutes and more particularly around 60 minutes is preferably used in this invention, which also depends on the volume of each component and composition of the powder mixture used. Then, a uniaxial pressure is applied to the heated mixture till the mixture gets densified, partially cured or fully cured, and extruded. The curing process can also be carried out separately after the part is extruded out. The pressing force applied can be ranged from 10 psi to 1000 psi depending on the viscosity of the softened mixture. The preferred pressure is between 10 psi to 500 psi, more preferred pressure is between 20 psi to 400 psi. In this invention, 75 psi is preferred for preparation of the samples. The dwelling time for the hot pressing can be from 1 minute to 1000 minutes depending on the nature of the mixture. The part can be extruded or pushed out of the die, and extra curing process at temperature ranging from 70 deg. C to 300° C. for 10 minutes to 2000 minutes might be used depending on the type and process conditions used.

The pressing is performed with pressing plates having a smooth surface with a surface roughness below 1.000 μm, preferred below 0.500 μm, more preferred below 0.200 μm or even lower. The surface of the pressing plates may comprise a coating of polyester, polyacrylate, fluoropolymer or polyethylene-terephthalate or mixtures thereof.

The invention is also directed to a composite material and a composite converter prepared by the method as described above.

### EXPERIMENTAL

The general process and method used in this invention to make composite converters can be described as below. The disclosure of the experiments shall be regarded solely for illustrative purposes and not as limiting the scope of the invention.

### Chemicals:

### PMSQ Powders:

Chemical composition: polymethylsilsesquioxane (PMSQ) or polysilsesquioxane (PSQ) chemicals used in this invention are a class of polymers refer to all structures with the empirical formulae [RSiO_{1.5}]ₙ basic structure, where R is hydrogen or any alkyl, alkylene, aryl, arylene, or organo-functional derivatives of alkyl, alkylene, aryl, or arylene groups.

Purity: >99.0%

Particle size: 10 nm to 300 μm, D50 ˜80 μm. Preferred range 100 nm to 50 μm, D50 ˜30 μm; more preferred range 100 nm to 30 μm, D50 ˜20 μm.

### Phosphors:

Different phosphors can be used either individually or as a mixture of different phosphors. Phosphors including white phosphor e.g. Gd and/or Ce doped YAG; green phosphor, e.g. Ce doped LuAG, LuYAG; amber phosphor e.g. Eu doped (Sr, Ba)₂Si₅N₈; IR and/or NIR phosphors e. g. La₃Ga₅GeO₁₄:Cr³⁺, ScBO₃:Cr³⁺, Gd₃Sc₂Ga₃O₁₂:Cr³⁺ and Mg₂SiO₄:Cr³⁺ etc.

Phosphors can be in single composition or mixture of different phosphors for different applications.

Phosphor purity: 99.9%

Phosphor QE: >80.0%; preferred >90.0%, more preferred >95.0% or higher.

Phosphor particle size: 10 nm to 50 μm, D50 ˜30 μm. Preferred range 50 nm to 30 μm, D50 ˜20 μm; more preferred range 100 nm to 20 μm, D50 ˜15 μm.

### Mixing Process:

Depending on the applications, certain amount of phosphor powders and PMSQ based polymer powders were weighed and mixed to achieve a homogeneous mixture of phosphors and PMSQ based polymers. The mixing can be achieved by different methods such as shaking, rolling, tumbling and ball milling etc. The preferred mixing is ball milling used in this invention. The mixing process time used is between 5 minutes to 24 hours depending on the methods and the characteristics of the starting chemicals. Following the mixing process described, three different mixtures of different compositions are prepared and listed in Table 1, 2 and 3.

TABLE 1
Mixture composition of phosphors and PMSQ polymer type A1 series

| | | Mass | Mass | | Vol | | phosphor |
|---|---|---|---|---|---|---|---|
| Material | Chemical Type | (g) | (%) | density | (ml) | vol % | % vol |
| PMSQ -A1 | Polymer -type | 20 | 62.2% | 1.08 | 18.52 | 87.6% | |
| | A | | | | | | |
| Phosphor | YAG:Ce | 1.774 | 5.5% | 4.65 | 0.38 | 1.8% | 12.38% |
| | phosphor 1 | | | | | | |
| Phosphor | YAG:Ce | 10.396 | 32.3% | 4.65 | 2.24 | 10.6% | |
| | phosphor 2 | | | | | | |
| Total | | 32.17 | 100.0% | 1.522 | 21.14 | 100.0% | |

TABLE 2
Mixture composition of phosphors and PMSQ polymer type A2 series

| | Chemical | Mass | Mass | | vol, | | phosphor |
|---|---|---|---|---|---|---|---|
| Material | lot | (g) | (%) | density | mL | vol % | % vol |
| PMSQ - A2 | Polymer | 24 | 66.4% | 1.08 | 22.22 | 89.5% | |
| | type A | | | | | | |
| Phosphor | YAG:Ce | 1.774 | 4.9% | 4.65 | 0.38 | 1.5% | 10.54% |
| | phosphor 1 | | | | | | |
| Phosphor | YAG:Ce | 10.396 | 28.7% | 4.65 | 2.24 | 9.0% | |
| | phosphor 2 | | | | | | |
| Total | | 36.17 | 100.0% | 1.456 | 24.84 | 100.0% | |

TABLE 3
Mixture composition of phosphors and PMSQ polymer type B series

| | Chemical | Mass | Mass | | Vol | | Phosphor |
|---|---|---|---|---|---|---|---|
| Material | lot | (g) | (%) | density | (ml) | vol % | % vol |
| PMSQ - B | Polymer | 26.00 | 68.1% | 1.4 | 18.57 | 87.6% | |
| | Type B | | | | | | |
| Phosphor | YAG:Ce | 1.774 | 4.6% | 4.65 | 0.38 | 1.8% | 12.35% |
| | phosphor 1 | | | | | | |
| Phosphor | YAG:Ce | 10.396 | 27.2% | 4.65 | 2.24 | 10.6% | |
| | phosphor 2 | | | | | | |
| Total | | 38.17 | 100% | 1.801 | 21.19 | 100.0% | |

### General Densification and Gelation Process:

Certain amount of mixed homogeneous powders of phosphor and PMSQ based polymer were weighed in a weighing boat. The weighed mixture powders were transferred into a pressing die with diameter ranging from 5 mm to 200 mm, the pressing die together with the mixture powders loaded was heated up to the softening or melting point, this could be from ˜70° C. to 400° C. depending on the type of PMSQ based polymer used. Further examples including the heat-up and the dwelling time is specified above. The temperature at softening point was held for certain period of time, e. g. from 2 minutes to 240 minutes, 60 minutes was used in this invention.

Then, a uniaxial pressure was applied to the heated mixture till the mixture was densified, partially cured or fully cured, and extruded. The pressure may range from 10 psi to 1000 psi depending on the viscosity of the softened mixture. The preferred pressure is between 10 psi to 500 psi, more preferred pressure is between 10 psi to 300 psi. The pressure of 75 psi was used for preparation of the samples in this invention. The dwelling time for the hot pressing can be from 1 minute to 1000 minutes depending on the nature of the mixture. Further examples are specified above. The part can be extruded or pushed out of die, and extra curing process at temperature ranging from 70° C. to 300° C. for 10 minutes to 2000 minutes might be used depending on the type and process conditions used.

### Optical Properties Measurements:

Quantum efficiency (QE) of the composite converter materials prepared was measured using a Quantaurus-Absolute quantum yield spectrometer by Hamamatsu. For white Gd/Ce doped YAG phosphor/polymer composite converter materials, 455 nm was used for excitation and three measurement data were collected to get an average value. The coupon sample in disc shape used for QE measurement is of diameter ˜17.5 mm, thickness from 0.05 mm to 1.00 mm.

Chromaticity (Cx, Cy) and brightness of the composite converter materials were measured using an in-house sphere photometry system. The platelet samples used in the sphere measurements are of the dimensions of ˜1030 μm×1030 μm or 1150 μm×1150 μm, which were diced from the pressed disc using a normal dicing machine.

### Surface Roughness (Sa) Measurements:

Surface roughness measurement was performed using Zygo optical profilometer. Data was collected on three areas on the surface of the prepared coupon samples.

Below are the examples to describe the basic process used in this invention.

### Example 1

Weigh ˜0.170 g pre-mixed A1 series of powder mixture (PMSQ powders and YAG:Ce phosphors), the weighed powder mixture was transferred into the uniaxial pressing die with a diameter of ˜17.50 mm, the powder mixture was homogeneously distributed on the surface of the bottom punch. The top punch was put into the die and the powder mixture was pressed under approximately 20 psi to form a light-pressed disc. The pressing die set was heated up to 150° C. with a ramp up rate 15° C. per minute, followed by holding for 30 minutes. The heated die set was then subjected to a uniaxial pressure of ˜75 psi by the top punch using a hydraulic system, and the pressure was held for 2 minutes. Then the pressure was released and the pressed densified disc was kept at 150° C. for 4 to 20 hours to make the gelatin/cross-link process of the polymer in the powder mixture completed. The disc shape sample had a thickness of ˜440 micrometers, and was used for QE and surface roughness measurements, results of which are listed in Tables 4 and 5.

### Example 2

The same condition as in example 1 was used but weighed less pre-mixed A1 powder mixture ˜0.07 g to make a thinner disc of thickness ˜180 micrometers, which was used for QE and surface roughness measurements, results of which are listed in Tables 4 and 5. Discs of thickness between 80 and 200 micrometers from this process were diced into platelets with dimension ˜1030×1030 μm for other optical properties measurements including chromaticity (Cx, Cy) and brightness etc. using an in-house designed sphere photometry measurement system.

### Examples 3 and 4

Similar amounts of A1 series powder mixtures were used, and the same procedures as described in example 1 were performed. Instead of 150° C. used when uniaxial pressure was applied as in example 1, 130° C. and 180° C. were used at which uniaxial pressure applied for examples 3 and 4, respectively. The disc shape samples were used for QE and surface roughness measurements and results are listed in Tables 4 and 5; the discs were diced into platelets of dimension ˜1030×1030 μm for optical properties measurement including chromaticity (Cx, Cy) and brightness etc. using an in-house designed sphere photometry measurement system.

### Examples 5 and 6

Small amounts of pre-mixed B series powder mixture 0.170 g and 0.060 g respectively for examples 5 and 6 were used, and the same procedure as described in example 1 was performed. Instead of 150° C. used when uniaxial pressure applied as in example 1, 70° C. was used at which uniaxial pressure of 75 psi applied for 2 minutes and then the pressure was released and the pressed densified disc was kept at 70° C. for 4 to 20 hours to allow PMSQ polymer to complete its gelation process. The disc shape samples were used for QE and surface roughness measurements. Results are listed in Tables 4 and 5. The disc shape samples were diced into platelets of dimension ˜1030×1030 μm for optical properties measurement including chromaticity (Cx, Cy) and brightness etc. using an in-house designed sphere photometry measurement system.

TABLE 4
quantum efficiency (QE) of white composite
converter materials measured at 455 nm

| | Quantum efficiency (QE) | | | | |
|---|---|---|---|---|---|
| Example | QE-1 | QE-2 | QE-3 | QE_Avg. | Stdev. |
| Example 1 | 98.5% | 98.9% | 98.5% | 98.6% | 0.0024 |
| Example 2 | 98.4% | 98.9% | 98.6% | 98.6% | 0.0026 |
| Example 3 | 98.7% | 100.1% | 99.7% | 99.5% | 0.0074 |
| Example 4 | 99.3% | 99.5% | 99.3% | 99.4% | 0.0012 |
| Example 5 | 98.7% | 99.2% | 98.8% | 98.9% | 0.0027 |
| Example 6 | 98.8% | 98.9% | 98.9% | 98.9% | 0.0006 |

TABLE 5
surface roughness (Sa) of composite converter
materials measured by Zygo optical profilometer

Example

| Test | Wet-process reference* | Example 5 | Example 1 |
|---|---|---|---|
| Run No. | Sa (μm) | Sa (μm) | Sa (μm) |
| 1 | 1.164 | 0.333 | 0.651 |
| 2 | 1.208 | 0.424 | 0.290 |
| 3 | 1.182 | 0.486 | 0.304 |
| Mean | 1.185 | 0.414 | 0.415 |
| Stdev. | 0.022 | 0.077 | 0.205 |

*Wet process reference - composite converter material made by gelation (cross-link) of liquid methoxy functionalized methyl polysiloxane based polymer induced by catalyst and moisture

### Examples 7, 8, 9 and 10

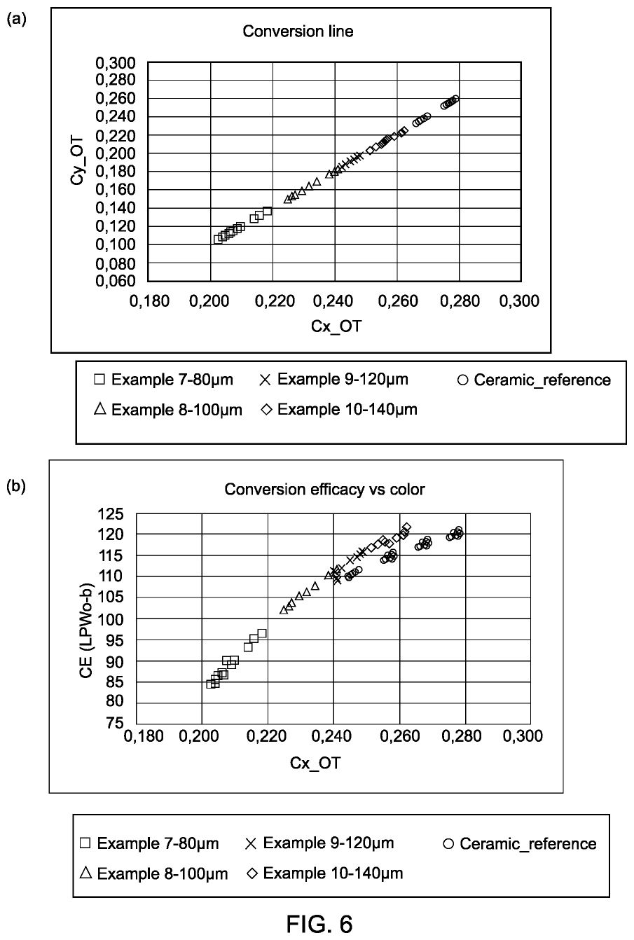

Following the same procedure as described in example 1, small amounts of A2 series powder mixtures were used, 0.060 g, 0.070 g 0.080 g and 0.090 g to make disc samples of different thicknesses ˜80 μm, ˜100 μm, ˜120 μm, ˜140 μm for examples 7, 8, 9 and 10, respectively. Instead of 150° C., 130° C. were used when uniaxial pressure was applied under 75 psi for 2 minutes, then the pressure was released and the pressed discs were kept at 100° C. to up to 130° C. for 4 to 18 hours to complete the gelation process. The disc shape samples were used for QE and surface roughness measurements; the dis samples were then diced into platelets of dimension ˜1030×1030 μm for optical properties measurements including chromaticity (Cx, Cy) and brightness etc. in an in-house designed sphere photometry measurement system. The optical properties are plotted in FIG. 6.

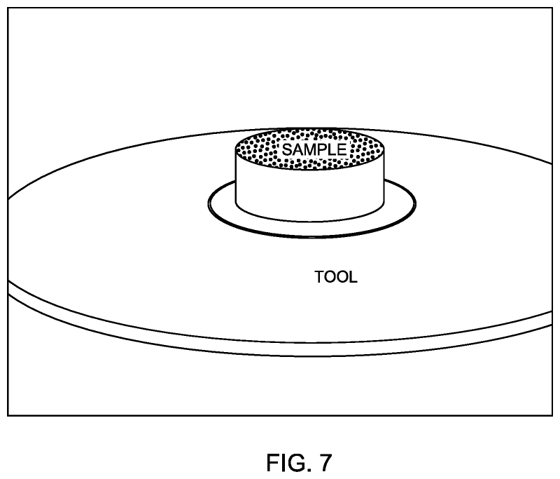

A typical white composite converter material made by this process in example 3 is given in FIG. 7.

### Examples 11, 12, 13, 14 and 15

Following the same procedure as described in example 1 but with a change of the phosphor type to make amber composite converters. In this invention for examples 11, 12, 13, 14 and 15, a mixture of amber powders consisted of (Sr, Ba) Si₂Al₂N₆, with ˜0.5 at % Eu doped and YAG:Ce with ˜3 at % Ce doped and PMSQ A type. The volume percent of the mixture powders for (Sr, Ba) Si₂Al₂N₆, YAG:Ce and PMSQ A type mentioned above were ˜18.3%, ˜15.9% and ˜65.8% respectively. The phosphor type, composition and mixture volume percent can be changed for different emission spectra, color points and applications.

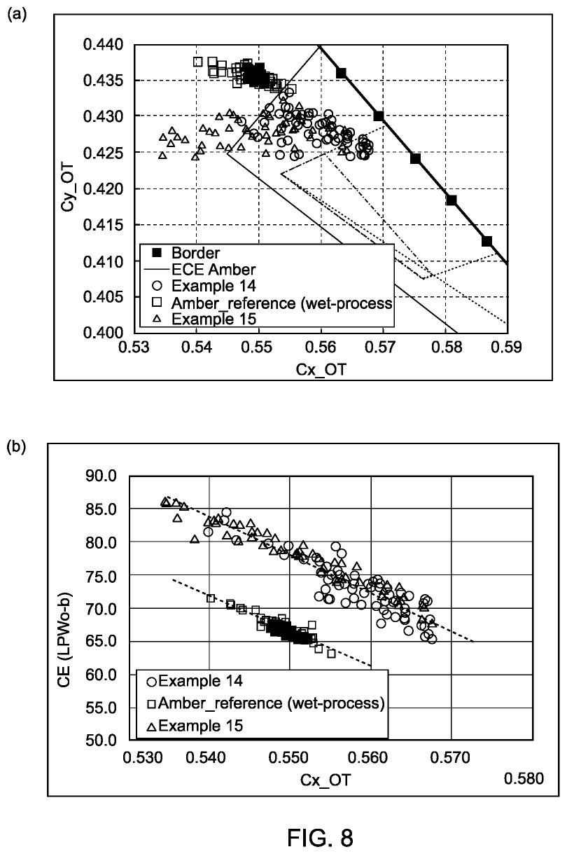

Small amounts of the mixture of amber powders with the weights of, 0.0703 g, 0.072 g, 0.100 g 0.112 g and 0.1280 g respectively were used to make disc samples of different thicknesses ˜140 μm, ˜160 μm, ˜200 μm, ˜250 μm respectively. The procedure described in example 1 was used, but with a change in the heat temperature to 180° C. and holding for 40 min, cooling down to 150° C. for 20 min, then uniaxial pressure was applied under 100 to 150 psi for 2 minutes. After release of pressure the discs were kept at 140° C. for 4 hr and then 180 ºC for 16 hours to allow PMSQ polymer gelation process to complete. The disc shape samples were used for QE and surface roughness measurements; the disc samples were then diced into platelets of dimension ˜1150×1150 μm for optical properties measurement including chromaticity (Cx, Cy) and brightness etc. using an in-house sphere photometry measurement system. QE was measured as average of 98% relative to the reference sample (composite converter made by wet process) and listed in table 6; Surface roughness measured as 0.414 micrometer on average of five areas and listed in table 7. The optical properties are plotted in FIG. 8 for examples 14 and 15, for comparison also included an amber reference sample by wet process made by gelation (cross-link) of liquid methoxy functionalized methyl polysiloxane based polymer induced by catalyst and moisture.

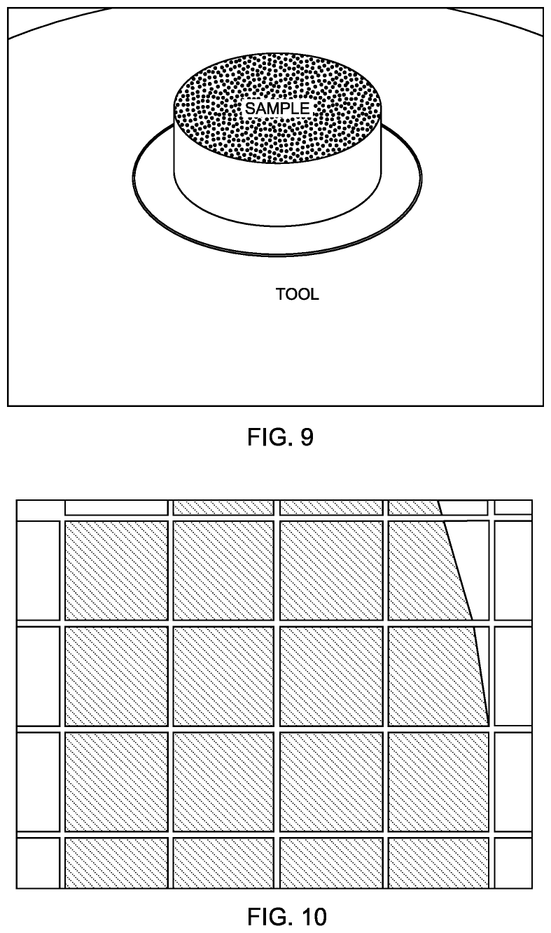

A typical amber composite converter material in disc shape made in this invention is given in FIG. 9 (example 13). Due to the different material composition the surface of amber composite converter material comprises a slightly different color compared to the example of FIG. 7. Further, the QE is slightly smaller compared to the material of Example 3 depicted in FIG. 7. Diced platelets image is given in FIG. 10.

TABLE 6
quantum efficiency (QE) of amber composite
converter materials measured at 455 nm

| | Quantum efficiency (QE) | | | | St. |
|---|---|---|---|---|---|
| Example | QE 1 | QE 2 | QE 3 | QE_Avg. | Dev |
| Example 11 | 97.8% | 98.1% | 98.4% | 98.1% | 0.003 |
| Example 12 | 97.4% | 97.9% | 98.1% | 97.8% | 0.004 |
| Example 13 | 98.0% | 98.1% | 98.6% | 98.2% | 0.003 |

TABLE 7
surface roughness (Sa) of Amber composite converter
materials measured by Zygo optical profilometer

| Sample run# | Sa (μm) | Area (μm²) |
|---|---|---|
| 1 | 0.505 | 626633.94 |
| 2 | 0.387 | 654859.18 |
| 3 | 0.571 | 672471.38 |
| 4 | 0.309 | 665946.36 |
| 5 | 0.280 | 670821.60 |
| Mean | 0.411 | 658146.49 |
| Std Dev | 0.125 | 18911.28 |

The advantages gained by the technical feature of the invention are as following:
Usage of dry solid starting chemicals with controlled molecular weight, as this solid chemicals, e.g PMSQ, which produces a very low shrinkage during gelation and densification processes, as these chemicals have higher molecular weight and density than their corresponding liquid form.
Application of heat/pyrolysis process makes gelation of polymers and densification between starting powders occur simultaneously, in which very low shrinkage can be expected and accommodated into dense part since no more additional liquid chemicals such as liquid vehicle or gelation catalyst are introduced.
Employment of external force—pressing and extruding and tools employed with flat and smooth surface will (1) help the densification and eliminate macro- and/or micro-cracks during gelation (cross-link); (2) generate a flat and smooth surface, hence converter part with low surface roughness and free of micro and macro cracks can be achieved.

1. Composite material comprising a phosphor and a polymer, wherein the polymer is selected from polymethylsilesquioxane (PMSQ) or polysilesquioxane (PSQ), and wherein the composite material has a surface roughness below 1.000 μm.

2. Composite material according to claim 1, wherein the amount of spikes and nodules with the height above 1.000 μm is reduced by more than 90%.

3. Composite material according to claim 1, wherein the phosphor is selected from white phosphor comprising Gd and/or Ce doped YAG, green phosphor, comprising Ce doped LuAG, LuYAG, amber phosphor comprising Eu doped (Sr, Ba)₂Si₅N₈, or IR and/or NIR phosphors comprising La₃Ga₅GeO₁₄:Cr³⁺, ScBO₃:Cr³⁺, Gd₃Sc₂Ga₃O₁₂:Cr³⁺ and Mg₂SiO₄:Cr³⁺ and mixtures thereof.

4. Composite material according claim 1, wherein the PMSQ or PSQ have a basic structure with the empirical formulae [RSiO_{1.5}]ₙ, wherein R is hydrogen or any alkyl, alkylene, aryl, arylene, or organo-functional derivatives of alkyl, alkylene, aryl, or arylene groups.

5. Composite material according to claim 1, wherein the phosphor has a particle size from 10 nm to 50 μm.

6. Composite material according to claim 1, wherein the PMSQ or PSQ comprise a particle size from 10 nm to 50 μm.

7. Composite material according to claim 1, wherein the composite material, its starting powder mixture of phosphors and PMSQ or PSQ powders, before gelation or cross-link occurred, comprises a softening point between 50° C. to 500° C.

8. Optoelectronic device comprising:
A semiconductor layer stack having an active layer in between to differently doped layer structure, the semiconductor layer stack configured to emit light through an emission surface;
the composite material according to claim 1 attached to the emission surface.

9. Method of manufacturing a composite material, comprising the steps:
a. Mixing phosphor powder and PMSQ or PSQ powder in a dry state;
b. Homogenizing the mixture;
c. pressing and extruding the mixture at a temperature as from 50° C. to 500° C.

10. Method according to claim 9, wherein the temperature for pressing and extruding is from 70° C. to 400° C. with a heat-up time to the temperature in the range of 5 min to 120 min and more particularly between 10 min to 60 min and with an optional dwelling time at the temperature is between 15 min and 60 min and particularly between 20 min and 50 min.

11. Method according to claim 9, wherein the pressing takes place under a pressure of 10 psi to 1000 psi.

12. Method according to claim 9, wherein the pressing is performed with pressing plates having a smooth surface with a surface roughness below 1.000 μm.

13. Method according to claim 12 wherein the surface of the pressing plates comprises a thin layer and or coating of polyester, polyacrylate, fluoropolymer, polyethylene-terephthalate, polyamide, polyether ether ketone, polyoxymethylene, or other polymers coming from similar groups.

14. Method according to claim 9, wherein the mixing and homogenizing is performed by rolling, shaking, ball milling or the like.

15. Composite material prepared by the method of claim 9.
